(19) United States
(12) Patent Application Publication
(10) Pub. No.: US 2006/0138545 A1
(43) Pub. Date: Jun. 29, 2006

(54) Protective circuit for protecting chip from misoperation

(75) Inventor: Heng-Chen Kuo, Tu-Cheng (TW)

Correspondence Address: MORRIS MANNING & MARTIN LLP, 1600 ATLANTA FINANCIAL CENTER, 3343 PEACHTREE ROAD, NE, ATLANTA, GA, 30326-1044, US

(73) Assignee: HON HAI Precision Industry CO., LTD., Tu-Cheng City (TW)

(21) Appl. No.: 11/300,696

(22) Filed: Dec. 15, 2005

(30) Foreign Application Priority Data
Dec. 24, 2004 (CN) 200410091837.8

(51) Int. Cl. H01L 23/62

(52) U.S. Cl. 257/355

(57) ABSTRACT

A protective circuit for a chip includes an input terminal for receiving a power supply voltage, an output terminal for outputting a working voltage to the chip, a first BJT and a second BJT. A base of the first BJT is connected to the input terminal and an emitter of the first BJT is grounded. A base of the second BJT is connected to a collector of the first BJT and an emitter of the second BJT is connected to the input terminal. A collector of the second BJT is connected to the output terminal.

### CROSS-REFERENCE TO RELATED APPLICATION

Related subject matter is disclosed in a co-pending U.S. Patent Application entitled “PROTECTIVE CIRCUIT FOR PROTECTING CHIP FROM MISOPERATION,” assigned to the same assignee with this application.

### BACKGROUND

1. Field of the Invention

The present invention relates to a protective circuit for a chip, and more particularly to a protective circuit for preventing a chip from misoperation.

2. General Background

In general, in a power supply circuit for a chip, a filter capacitor is connected to a power supply in order to stabilize waveform of an input voltage for the chip. However, when the power supply is turned on or turned off instantly, the waveform of the input voltage is slowly changed because of the filter capacitor. Thus, the chip will be in an unstable state between a work state and a close state. The chip in an unstable state will carry out a misoperation.

A common method to prevent the chip from misoperation is to use a Reset IC (Integrated Circuit) in a power supply circuit, such as DS1233Z, LMS33460, TL7705A, TL7757A and etc. The Reset IC has a voltage reset and test functions. However, a circuit structure of such a Reset IC is complex. In addition, a voltage that the IC can test is non-adjustable. So the power supply circuit should use different Reset ICs to prevent different chips from misoperation.

What is needed is a protective circuit for preventing a chip from misoperation which has a simple structure and low cost.

### SUMMARY

A protective circuit for a chip includes an input terminal for receiving a power supply voltage, an output terminal for outputting a working voltage to the chip, a first BJT and a second BJT. A base of the first BJT is connected to the input terminal and an emitter of the first BJT is grounded. A base of the second BJT is connected to a collector of the first BJT and an emitter of the second BJT is connected to the input terminal. A collector of the second BJT is connected to the output terminal.

When the power supply voltage is more than a least working voltage of the chip, the first BJT is turned on and outputs a low level voltage to the second BJT. Then the second BJT is turned on, so the chip is at a work mode. When the power supply voltage is less than the least working voltage of the chip, the first BJT is turned off and outputs a high level voltage to the second BJT. Then the second BJT is turned off, so the chip is closed. So the protective circuit can prevent the chip from misoperation when the power supply voltage is less than the least working voltage of the chip.

Other advantages and novel features will become more apparent from the following detailed description when taken in conjunction with the accompanying drawings, in which:

### BRIEF DESCRIPTION OF THE DRAWINGS

FIG. 1 is a schematic diagram of a protective circuit in accordance with a preferred embodiment of the present invention, together with one chip;

FIG. 2 is the schematic diagram of the protective circuit of FIG. 1, together with two chips; and

FIG. 3 is a circuit diagram of a voltage detecting circuit and a voltage switching circuit of the FIG. 1 and FIG. 2.

### DETAILED DESCRIPTION OF THE EMBODIMENTS

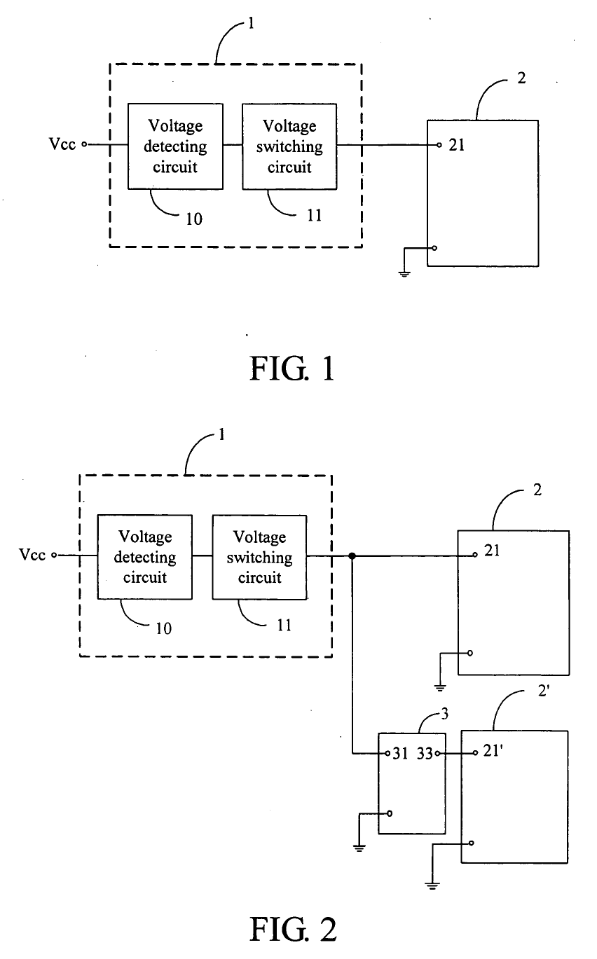

Referring to FIG. 1, a protective circuit 1 in accordance with a preferred embodiment of the present invention is applied to prevent an electronic component like a chip 2 from misoperation. The protective circuit 1 includes a voltage detecting circuit 10 and a voltage switching circuit 11. An output terminal of the voltage detecting circuit 10 is connected to an input terminal of the voltage switching circuit 11. An output terminal of the voltage switching circuit 11 is connected to an input terminal 21 of the chip 2. A power supply voltage used as a power source is inputted to the protective circuit 1 via a Vcc terminal. The voltage detecting circuit 10 detects a value of the power supply voltage and outputs a control signal to the voltage switching circuit 11, according to the value of the power supply voltage. The control signal from the voltage detecting circuit 10 controls the voltage switching circuit 11 to turn on or turn off, thereby controlling the chip 2 to work or close.

Referring FIG. 2, the protective circuit 1 can also be applied to prevent two chips, that is, the chip 2 and a chip 2′ from misoperation. The least working voltage of the chip 2 is different from the least working voltage of the chip 2′. A voltage converter 3 is connected between the chip 2′ and the protective circuit 1 to convert a voltage from the protective circuit 1 to another voltage for the chip 2′. The output terminal of the voltage switching circuit 11 is connected to the input terminal 21 of the chip 2 and an input terminal 31 of the voltage converter 3. An output terminal 33 of the voltage converter 3 is connected to an input terminal 21′ of the chip 2′. A type of the voltage converter 3 can be selected according to a ratio of the least working voltage of the chip 2 to the least working voltage of the chip 2′.

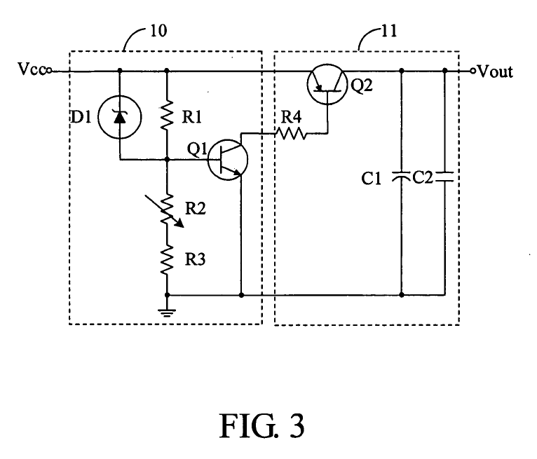

Referring FIG. 3, the voltage detecting circuit 10 includes a Bipolar Junction Transistor (BJT) Q1 and a Zener Diode D1. The BJT Q1 is a NPN transistor. The Vcc terminal is grounded via a resistor R1, an adjustable resistor R2 and a resistor R3 in turn. A base of the BJT Q1 is connected to a node between the resistor R1 and the resistor R2. A Zener Diode D1 is connected between the Vcc terminal and the node, and in parallel with the resistor R1. The Zener Diode D1 is used to stabilize the power supply voltage. An emitter of the BJT Q1 and the resistor R3 are grounded. The voltage switching circuit 11 includes a BJT Q2. The BJT Q2 is a PNP transistor. A base of the BJT Q2 is connected to a collector of the BJT Q1 via a resistor R4. An emitter of the BJT Q2 is connected to the Vcc terminal, and a collector of the BJT Q2 is connected to a Vout terminal. A capacitor C1 is connected between the collector of the BJT Q2 and the emitter of the BJT Q1. A capacitor C2 is connected to the capacitor C1 in parallel. The capacitor C1 and the capacitor C2 are used to filter an output voltage of the BJT Q2.

Presuming that a turn-over voltage of the BJT Q1 is VQ1, a turn-over voltage of the BJT Q2 is VQ2, the least working voltage of the chip 2 is Vchip2, a voltage of the base of the BJT Q1 is Vb, and the power supply voltage is Vcc. If Vcc≧VQ2+Vchip2, a partial voltage of the resistor R2 and the resistor R3 is more than the turn-over voltage of the BJT Q1, thereby the BJT Q1 is turned on and works in a saturation region. Therefore an output voltage of the collector of the BJT Q1 is at a low level, that is, an input voltage of the base of the BJT Q2 is at a low level. Because the BJT Q2 is a PNP transistor, the BJT Q2 is turned on. Therefore the Vout terminal outputs a voltage to the chip 2. Thus, the chip 2 is at a work mode. If Vcc≦VQ2+Vchip2, the partial voltage of the resistor R2 and the resistor R3 is less than the turn-over voltage of the BJT Q1, thereby the BJT Q1 is turned off. Therefore an output voltage of the collector of the BJT Q1 is at a high level and the BJT Q2 is turned off. Thus, the chip2 is closed. Because the voltage converter 3 can convert a voltage to another proper voltage for the chip 2′, the chip 2′ is at a work mode when Vcc≧VQ2+Vchip2, and the chip2′ is closed when Vcc≦VQ2+Vchip2.

Values of the resistors R1, R2, R3 can be selected according a relationship of the Vchip, the VQ2 and the Vb, that is:

$$\frac{Vchip 2 + VQ 2}{Vb} = \frac{R 1 + R 2 + R 3}{R 2 + R 3}$$

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments.

What is claimed is:

1. A protective circuit for protecting a chip from misoperation, the protective circuit comprising:
an input terminal for receiving a power supply voltage;
an output terminal for outputting a working voltage to the chip;
a first Bipolar Junction Transistor (BJT) comprising a base connected to the input terminal, an emitter being grounded, and a collector; and
a second BJT comprising a base connected to the collector of the first BJT, an emitter connected to the input terminal, and a collector connected to the output terminal.

2. The protective circuit as claimed in claim 1, wherein a polarity of the first BJT is contrary to a polarity of the second BJT.

3. The protective circuit as claimed in claim 1, wherein the voltage detecting circuit further comprises a Zener Diode for stabilizing the power supply voltage, and the Zener Diode is connected between the input terminal and the base of the first BJT.

4. The protective circuit as claimed in claim 1, wherein the voltage switching circuit further comprises a capacitor for filtering an output voltage of the second BJT, and the capacitor is connected between the collector of the second BJT and a ground.

5. The protective circuit as claimed in claim 1, wherein a first resistor and a second resistor are connected between the input terminal and ground, and the base of the first BJT is connected to a node between the first resistor and the second resistor.

6. A protective circuit for protecting a chip from misoperation, the protective circuit comprising:
a voltage detecting circuit for detecting a value of a power supply voltage, the voltage detecting circuit comprising an input terminal receiving a power supply voltage and an output terminal outputting a control signal; and
a voltage switching circuit to turn on or turn off the chip according to the control signal from the voltage detecting circuit, the voltage switching circuit comprising an input terminal receiving the control signal and an output terminal connected to the chip.

7. The protective circuit as claimed in claim 6, wherein the voltage detecting circuit comprises a first Bipolar Junction Transistor (BJT), a base of the first BJT receives the power supply voltage, and an emitter of the first BJT is grounded.

8. The protective circuit as claimed in claim 7, wherein the voltage switching circuit comprises a second BJT, a base of the second BJT is connected to a collector of the first BJT, an emitter of the second BJT receives the power supply voltage, and a collector of the second BJT is connected to the output terminal of the voltage switching circuit.

9. The protective circuit as claimed in claim 8, wherein a polarity of the first BJT is contrary to a polarity of the second BJT.

10. The protective circuit as claimed in claim 6, wherein the voltage detecting circuit further comprises a Zener Diode for stabilizing the power supply voltage.

11. The protective circuit as claimed in claim 6, wherein the voltage switching circuit further comprises a capacitor for filtering an output voltage of the second BJT.

12. The protective circuit as claimed in claim 6, wherein the output terminal of the voltage switching circuit is connected to another chip via a voltage converter.

13. A method for ensuring normal operation of an electronic component, comprising the steps of:
electrically connecting a voltage detecting circuit between an electronic component and a power source capable of activating said electronic component;
electrically connecting a voltage switching circuit between said voltage detecting circuit and said electronic component;
detecting supplying voltage of said power source by means of said voltage detecting circuit for providing a control signal to said voltage switching circuit;
electrically connecting said power source and said electronic component by means of said voltage switching circuit based on said control signal of said voltage detecting circuit when said detected voltage is higher than a threshold voltage preset selectively according to said voltage switching circuit and said electronic component; and
disconnecting said power source and said electronic component by means of said voltage switching circuit based on said control signal of said voltage detecting circuit when said detected voltage is lower than said threshold voltage.

14. The method as claimed in claim 13, wherein said voltage detecting circuit comprises a first Bipolar Junction Transistor (BJT), and said voltage switching circuit comprises a second BJT.
